(19) United States
(12) Patent Application Publication
(10) Pub. No.: US 2025/0094052 A1
(43) Pub. Date: Mar. 20, 2025

(54) MEMORY DEVICE AND OPERATING METHOD THEREOF

(71) Applicant: Samsung Electronics Co., Ltd., Suwon-si (KR)

(72) Inventor: SUK-HYUN LIM, Suwon-si (KR)

(21) Appl. No.: 18/605,982

(22) Filed: Mar. 15, 2024

(30) Foreign Application Priority Data
Sep. 20, 2023 (KR) 10-2023-0125794

(51) Int. Cl. G06F 3/06

(52) U.S. Cl. CPC G06F 3/0611; G06F 3/0659; G06F 3/0673

(57) ABSTRACT

A memory device according to some embodiments includes a plurality of memory banks, a plurality of registers, a data I/O buffer configured to transmit and receive data, and a control logic configured to receive a low latency bit and an address that is preset according to a type of the data. The control logic is configured to determine a logic level of the low latency bit. Based on the low latency bit, the control logic is configured to store the data in a memory bank corresponding to the address among the plurality of memory banks or a register corresponding to the address among the plurality of registers or reads the data from the memory bank corresponding to the address or the register corresponding to the address.

### CROSS-REFERENCE TO RELATED APPLICATION

This application claims priority to and the benefit of Korean Patent Application No. 10-2023-0125794 filed at the Korean Intellectual Property Office on Sep. 20, 2023, the entire contents of which are incorporated herein by reference.

### BACKGROUND

The present disclosure relates to a memory device and an operating method thereof.

A semiconductor memory that is used as a memory device in most electronic systems has recently needed larger capacity and faster speed. Various attempts have been made to provide more memory capacity within a small area in order to increase the capacity of the memory, and various attempts have been made to efficiently drive the memory in order to increase a speed of the memory. In order to improve a degree of integration of the semiconductor memory, a 3-dimensional (3D) structure including a plurality of stacked memory chips is being used instead of a 2-dimensional (2D) structure.

On the other hand, because each access to the stacked memory devices by an external device requires data communication between the stacked semiconductor dies, an inter-device bandwidth and delay time between the external device and the stacked memory devices may increase. When the external device requires the access to the memory device, the bandwidth and the delay time significantly affect process efficiency and electric power consumption of a system.

### SUMMARY

The present disclosure is to reduce a latency during input/output of data within a memory device.

A memory device according to some embodiments includes a plurality of memory banks, a plurality of registers, a data I/O buffer configured to transmit and receive data, and a control logic configured to receive a low latency bit and an address that is preset according to a type of the data. The control logic is configured to determine a logic level of the low latency bit. Based on the low latency bit, the control logic stores the data in a memory bank corresponding to the address among the plurality of memory banks or a register corresponding to the address among the plurality of registers or reads the data from the memory bank corresponding to the address or the register corresponding to the address.

A memory device according to some embodiments includes a buffer die configured to transmit and receive data to and from a host device and include a plurality of registers configured to store the data, a plurality of memory dies that are stacked on the buffer die and include a plurality of memory banks configured to store the data, and a plurality of through silicon vias that electrically connect the buffer die to respective ones of the plurality of memory dies. The buffer die further includes a control logic configured to receive a low latency bit. The control logic is configured to determine a logic level of the low latency bit. The control logic is configured to receive an address that is preset according to a type of the data, and based on the low latency bit, the memory device is configured to store the data in a memory bank corresponding to the address among the plurality of memory banks or a register corresponding to the address among the plurality of registers, or read the data from the memory bank corresponding to the address or the register corresponding to the address.

An operating method of the memory device according to some embodiments includes receiving, by a memory device that includes a buffer die including a plurality of registers and at least one memory die stacked on the buffer die and including a plurality of memory banks, data, a low latency bit that is preset according to a type of the data, a command, and an address from a host device, and determining a logic level of the low latency bit. When the command is a write command, the operating method of the memory device includes mapping the address to at least one register address among a plurality of register addresses when the logic level of the low latency bit is at a first level, generating a mapping table including a mapping relationship between the address and the register address, and storing the data in a register corresponding to the mapped register address.

### BRIEF DESCRIPTION OF THE DRAWINGS

FIG. 1 is a block diagram showing a memory system according to some embodiments.

FIG. 2 is a perspective view showing a memory system according to some embodiments.

FIG. 3 is a block diagram showing a memory device according to some embodiments.

FIG. 4 is a flowchart showing a register write operation according to some embodiments.

FIG. 5 is a view showing a mapping table according to some embodiments.

FIG. 6 is a view showing a mapping table according to some embodiments.

FIG. 7 is a flowchart showing a register read operation according to some embodiments.

FIG. 8 is a perspective view showing a memory system according to some embodiments.

FIG. 9 is a perspective view showing a memory system according to some embodiments.

FIG. 10 is a perspective view showing a memory device according to some embodiments.

FIG. 11 is a perspective view showing an example of a semiconductor package including a stacked memory device according to some embodiments.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Accordingly, the drawings and description are to be regarded as illustrative in nature and not restrictive. Like reference numerals designate like elements throughout the specification. In the flowchart described with reference to the drawings, an order of operations may be changed, various operations may be merged, a certain operation may be divided, and a certain operation may not be performed.

In addition, a singular form may be intended to include a plural form as well, unless the explicit expression such as “one” or “single” is used. Terms including ordinal numbers such as first, second, and the like will be used only to describe various constituent elements, and are not to be interpreted as limiting these constituent elements. These terms may be used for a purpose of distinguishing one constituent element from other constituent elements.

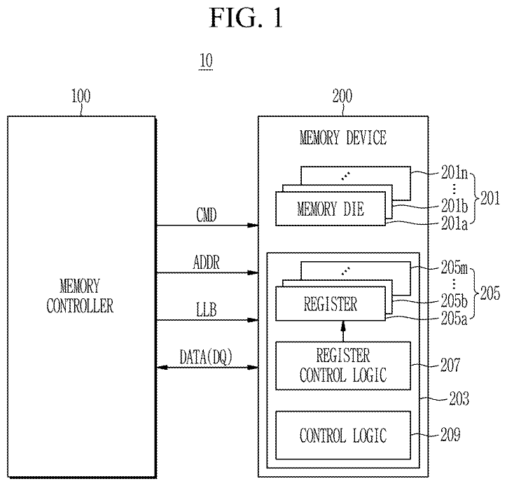

FIG. 1 is a block diagram showing a memory system according to some embodiments.

Referring to FIG. 1, the memory system 10 may include a memory controller 100 and a memory device 200.

In some embodiments, the memory device 200 and the memory controller 100 may be electrically connected through a memory interface to exchange signals through the memory interface. On the other hand, a type of the signal transmitted between the memory device 200 and the memory controller 100 may be preset, and the memory device 200 and the memory controller 100 may exchange the signals according to the preset type.

The memory controller 100 may access the memory device 200 according to a request from an external host. The memory controller 100 may control a memory operation of the memory device 200 by providing a signal to the memory device 200. The signal may include a command CMD and an address ADDR. In some embodiments, the signal may further include a low latency bit LLB.

The command CMD may include a read/write command. The read/write command may be a command for performing a read operation reading data stored in the memory device 200 or a write operation writing data in the memory device 200.

The low latency bit LLB may be preset by the memory controller 100 depending on a type of data DATA transferred to the memory device 200 or a type of data DATA received from the memory device 200. For example, the memory controller 100 may set the low latency bit LLB to an enable level (e.g., logic low or logic high) in a case in which the data DATA transferred to the memory device 200 are frequently used within the memory device 200, in a case in which the data DATA transferred to the memory device 200 need a faster processing speed, and the like. On the other hand, a type of the data DATA in which the low latency bit LLB is set to the enable level may be different depending on the memory system 10.

The memory device 200 may be a storage device based on a semiconductor element.

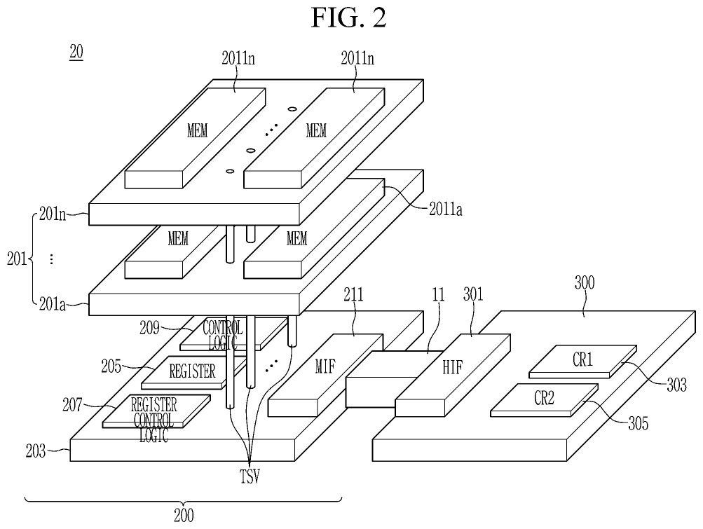

The memory device 200 may include a plurality of memory dies 201 and a buffer die 203. In some embodiments, the memory device 200 may be a stacked memory device. The memory device 200 may include the buffer die 203 and the plurality of memory dies 201 that are stacked on the buffer die 203 and are configured to store data. In the present specification, the memory die 201 may be referred to as a core die. A structure of the memory device 200 will be described later with reference to FIG. 2.

Each of the plurality of memory dies 201 may include a plurality of memory banks that store data. Each of the plurality of memory banks may include a memory cell array. The memory cell array may include a plurality of memory cell rows that respectively include a plurality of volatile memory cells, and the volatile memory cells included in one memory cell row may be connected to a corresponding word line and a plurality of bit lines.

Each of the plurality of memory dies 201 may be a dynamic random access memory (DRAM) including a plurality of volatile memory cells such as a thyristor random access memory (TRAM), a static random access memory (SRAM), a double data rate synchronous dynamic random access memory (DDR SDRAM), or the like. In some embodiments, each of the plurality of memory dies 201 may be a phase change random access memory (PRAM) including resistive memory cells, a resistive random access memory (RRAM), a magnetic random access memory (MRAM), or a ferroelectric random access memory (FRAM).

The buffer die 203 may communicate with the memory controller 100. The buffer die 203 may include a control logic 209, a register control logic 207, and a plurality of registers 205.

The control logic 209 may decode the command CMD received from the memory controller 100 to generate a read command, a write command, and the like. If the command CMD is the write command, the control logic 209 may transfer the data DATA to the memory die 201 based on the address ADDR. If the command CMD is the read command, the control logic 209 may transfer the data DATA read from the memory die 201 to the memory controller 100 based on the address ADDR. In some embodiments, if the command CMD is the write command and the low latency bit LLB is in an enabled state, the control logic 209 may transfer the received data DATA to the register control logic 207. In some embodiments, if the command CMD is the read command and the low latency bit LLB is in an enabled state, the control logic 209 may transfer data read from the register to the memory controller 100.

The plurality of registers 205 may store the data DATA received from the memory controller 100. For example, the register 205 may include a plurality of flip-flops, a plurality of latches, or the like. A register address may be assigned (or allocated) to corresponding ones of the plurality of registers 205.

The memory device 200 may include a register having an appropriate size depending on a type of the memory system 10. The size of the register may be preset based on the number of DQ pins and a burst length BL of the memory. For example, the register may have a size corresponding to one page of the memory die 201. For example, the register may have a size (that is, a size of #DQ×BL) corresponding to data that may be read or written at one time. In some embodiments, the memory device 200 may include registers having various sizes.

The register control logic 207 may be activated when the low latency bit LLB is in an enabled state.

In some embodiments, the register control logic 207 may include a mapping table including a mapping relationship between the address ADDR and the register address. The register control logic 207 may determine whether the data DATA is written in the register address based on the mapping table. The register control logic 207 may convert the received address ADDR to the register address based on the mapping table.

If the control logic 209 receives the write command and the register control logic 207 is activated, the register control logic 207 may write the received data DATA in the register. If the control logic 209 receives the read command and the register control logic 207 is activated, the register control logic 207 may read data from the register 205.

FIG. 2 is a perspective view showing the memory system according to some embodiments.

Referring to FIG. 2, the memory system 20 may include a host device 300 and the memory device 200. The memory device 200 may include the plurality of memory dies 201 and the buffer die 203, and the memory dies 201 may include memory dies 201a, . . . , 201n sequentially stacked.

In some embodiments, the host device 300 may include the memory controller 100 of FIG. 1, and the memory controller 100 of FIG. 1 and the memory device 200 may be part of the memory system. However, the present disclosure is not limited thereto, and the memory controller 100 of FIG. 1 may be included in the memory device 200, and a memory interface 211 may include the memory controller. In this case, the memory interface 211 may include receivers, line drivers, memory request buffers, a scheduling logic, a row/column decode logic, a refresh logic, data-input and data-output buffers, a clock generator, or the like.

The memory system 20 may include various computer systems including a notebook computer, a tablet computer, a desktop computer, a server, a network router, a switch, a hub, a computing mobile phone, a personal portable information terminal, and the like. On the other hand, an example in which the memory system 20 includes the host device 300 connected to the stacked memory device 200 through an interconnect device 11 is shown in the drawings, but the memory system 20 may include various configurations such as a display device, a storage device, an input device (e.g., a mouse or a keyboard), and the like that are not shown in the drawings.

The memory device 200 may include at least one buffer die 203 and the plurality of memory dies 201 vertically stacked. FIG. 2 shows one buffer die and two memory dies, but the present disclosure is not limited thereto, and the memory device 200 may include any number of memory dies. Additionally, although FIG. 2 shows that the buffer die 203 is vertically stacked at an upper portion of the memory die 201, the present disclosure is not limited thereto, and may have various shapes. For example, the memory dies 201, other than the buffer die 203 in the memory device 200, may be vertically stacked, and the buffer die 203 may be electrically connected to the stacked memory dies 201 through an interposer or a base substrate.

The buffer die 203 may include the memory interface (MIF) 211 and a logic for enabling access to memory integrated circuits (MEM) 2011a, . . . , 2011n disposed at the memory die 201. For example, the buffer die 203 may include the control logic 209, the register control logic 207, and the register 205.

The memory interface circuit 211 may be connected to a through silicon via TSV. The control logic 209 may transfer data provided from at least one of the memory dies 201 through the through silicon via to the host device 300 through the memory interface circuit 211. The control logic 209 may transfer data received from the host device 300 through the memory interface circuit 211 to at least one of the memory dies 201 through the through silicon via TSV.

The plurality of memory dies 201 may be connected to the buffer die 203 through the through silicon via TSV.

Each of the plurality of memory dies 201 may include the plurality of memory integrated circuits (MEM) 2011a, . . . , 2011n. Each of the plurality of memory integrated circuits 2011a, . . . , 2011n may include a plurality of memory banks that store data.

The host device 300 may include a host interface (HIF) 301 and processor cores (CR1 and CR2) 303 and 305. The host interface 301 communicates with an external device such as the stacked memory device 200 through the interconnect device 11.

In some embodiments, the host device 300 may be implemented as an integrated circuit (IC) package, and the memory device 200 may be implemented as an integrated circuit package distinguished from the host device 300. In some embodiments, the host device 300 and the memory device 200 may be implemented as separate sets of semiconductor dies connected to the same integrated circuit package through an interposer or the like.

In some embodiments, the host device 300 may be a process device that includes one or more process cores 303 and 305. For example, the process cores 303 and 305 may include various types of process cores such as a central processing unit (CPU) core, a graphic processing unit (GPU), a digital signal processor (DSP), and the like, and a combination thereof.

The interconnect device 11 may be implemented according to various conventional interconnect or bus architectures such as a Peripheral Component Interconnect-Express (PCI-E) architecture, a HyperTransport architecture, a QuickPath Interconnect (QPI) architecture, and the like. The interconnect device 11 includes one or more conductive lines that connect a transmission and reception circuit of the memory interface 211 and a transmission and reception circuit of the host interface 301 of the host device 300. The conductive lines may include electrically conductive lines such as traces of a printed circuit board (PCB) or cable lines, light conductive lines such as optical fibers, or conductive lines made of a combination thereof.

The memory device 200 of FIG. 2 may be implemented in a vertically stacked arrangement so that electric power and a signal are transferred between the buffer die 203 and the memory die 201 using dense through silicon vias (TSVs) or other vertical interconnects. Although FIG. 2 shows the TSVs as a set of centrally concentrated rows, the present disclosure is not limited thereto, and the TSVs may be distributed across planes of the semiconductor dies.

Data communication between the stacked semiconductor dies may be required when the stacked semiconductor dies are used to improve a degree of integration of the semiconductor memory, so that a time required for an access between the external device and the memory die further increases. Accordingly, a time required to read data from the register 205 may be less than a time required to read data from the memory die 201.

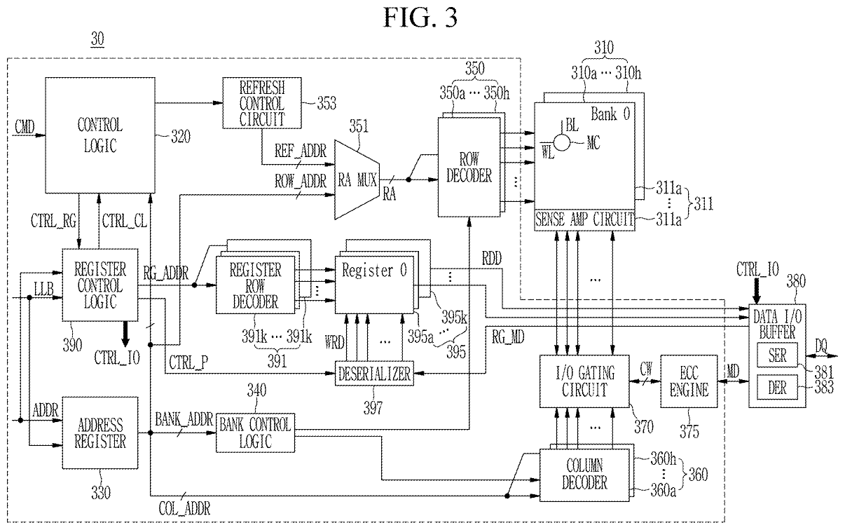

FIG. 3 is a block diagram showing the memory device according to some embodiments.

Referring to FIG. 3, the memory device 30 may include a memory cell array 310, a sense amplifier circuit 311, a control logic 320, an address register 330, a bank control logic 340, a row decoder 350, a column decoder 360, an input/output (I/O) gating circuit 370, an ECC (Error Correction Coding) engine 375, and a data I/O buffer (or a data input/output buffer) 380. Furthermore, the memory device 30 may further include a register control logic 390, a register row decoder 391, a register 395, and a deserializer 397.

On the other hand, although FIG. 3 shows that the sense amplifier circuit 311, the row decoder 350, and the column decoder 360 include a plurality of sense amplifier circuits connected to memory banks, a plurality of row decoders, and a plurality of column decoders, the present disclosure is not limited thereto.

The memory cell array 310 may include a plurality of memory cells MC. In some embodiments, the memory cell array 310 may include a plurality of memory banks 310a-310h. FIG. 3 shows eight memory banks (BANK0-BANK7) 310a-310h, but the number of the memory banks is not limited thereto. Each of the memory banks 310a-310h may include a plurality of rows, a plurality of columns, and the plurality of memory cells MC disposed at intersections (or intersecting points) of the plurality of rows and the plurality of columns. The memory cell MC may include one transistor and one capacitor. In some embodiments, the plurality of rows may be defined by a plurality of word lines WL, and the plurality of columns may be defined by a plurality of bit lines BL. The memory device 30 may perform a read operation or a write operation of data DQ for the plurality of memory cells MC.

The sense amplifier circuit 311 may include a plurality of bit line sense amplifiers connected to the plurality of bit lines BL of the memory cell array 310. The plurality of bit line sense amplifiers may sense (or detect) data input and output through the bit line BL, and may input and output the sensed data.

The control logic 320 may control an overall operation of the memory device30. For example, the control logic 320 may generate a control signal so that the memory device 30 performs the read operation or the write operation. The control logic 320 may include a command decoder for decoding the command CMD received from the memory controller (e.g., 100 of FIG. 1), a mode register for setting an operation mode of the memory device 30, and the like.

Specifically, the control logic 320 may generate a register control signal CTRL_RG so that the register control logic 390 performs a register read operation or a register write operation based on the command CMD.

The address register 330 may receive the address ADDR provided from the memory controller 100 of FIG. 1. The address ADDR may include a bank address BANK_ADDR, a row address ROW_ADDR indicating a row of the memory cell array 310, and a column address COL_ADDR indicating a column of the memory cell array 310. The address register 330 may provide the received bank address BANK_ADDR to the bank control logic 340, may provide the received row address ROW_ADDR to a row address multiplexer 351, and may provide the received column address COL_ADDR to the column decoder 360.

The bank control logic 340 may generate bank control signals in response to the bank address BANK_ADDR. In response to the bank control signals, the row decoder 350 and the column decoder 360 may activate the bank corresponding to the bank control signals. In response to the bank control signal, the row decoder 350 corresponding to the bank address BANK_ADDR among the plurality of row decoders 350a-350h may be activated, and the column decoder 360 corresponding to the bank address BANK_ADDR among the plurality of column decoders 360a-360h may be activated.

The row address multiplexer 351 may receive the row address ROW_ADDR from the address register 330, and may receive a row address REF_ADDR of a row of the memory cell array 310 to be refreshed from a refresh control circuit 353. The row address multiplexer 351 may selectively output the row address ROW_ADDR received from the address register 330 and the row address REF_ADDR received from the refresh control circuit 353 to the row decoder 350.

The row decoder 350 may select a row to be activated among the plurality of rows of the memory cell array 310 based on the row address ROW_ADDR or REF_ADDR received from the row address multiplexer 351. To this end, the row decoder 350 may apply a driving voltage to a word line corresponding to the row to be activated. In some embodiments, the plurality of row decoders 350a-350h respectively corresponding to the plurality of memory banks 310a-310h may be provided.

The column decoder 360 may select a column to be activated among the plurality of columns of the memory cell array 310 based on the column address. To this end, the column decoder 360 may activate the sense amplifier circuit 311 corresponding to the column address COL_ADDR through the I/O gating circuit 370. In some embodiments, the plurality of column decoders 360a-360h respectively corresponding to the plurality of memory banks 310a-310h may be provided.

The I/O gating circuit 370 may gate input/output data, and may include a data latch for storing data read from the memory cell array 310 and a write driver for writing data in the memory cell array 310. The data read from the memory cell array 310 may be sensed by the sense amplifier circuit 311, and may be stored in the I/O gating circuit 370. For example, the data read from the memory cell array 310 may be stored in the data latch of the I/O gating circuit 370. Specifically, one of the first to eighth memory banks 310a-310h may be sensed (or detected) by one of the sense amplifiers 311a-311h corresponding to the memory bank, and may be stored in the data latch of the I/O gating circuit 370. In this case, data sensed from the memory bank may be stored as a codeword CW in the I/O gating circuit 370. The I/O gating circuit 370 may transfer the codeword CW to the ECC engine 375 or may receive the codeword CW from the ECC engine 375.

The ECC engine 375 may perform ECC decoding on the codeword CW stored in the I/O gating circuit 370. When an error is detected in the codeword CW, the ECC engine 375 may generate an error generation signal while correcting the error, and may provide the corrected codeword CW as main data MD to the memory controller 100 of FIG. 1 through the data I/O buffer 380.

Additionally, the ECC engine 375 may perform ECC decoding on main data MD received through the data I/O buffer 380. Specifically, the ECC engine 375 may generate parity bits based on the main data MD, and may provide the main data MD and the parity bits as the codeword CW to the I/O gating circuit 370. The I/O gating circuit 370 may write the codeword CW in the memory cell array 310 through the write driver within the I/O gating circuit 370.

The data I/O buffer 380 may provide data (for example, data stored in the data latch) read from the memory cell array 310 to the memory controller 100 of FIG. 1. The data I/O buffer 380 may receive data to be written in the memory cell array 310 from the memory controller 100 of FIG. 1, and may provide the received data to the ECC engine 375.

The data I/O buffer 380 may include a serializer (SER) 381 and a deserializer (DES) 383.

The serializer 381 may convert parallel data to serial data. For example, the serializer 381 may be an i:j serializer that converts parallel data of i-bits to serial data of j-bits. Here, i and j may be positive numbers, and i may be greater than j. On the other hand, each of the codeword CW and the main data MD may be parallel data. For example, the serializer 381 may convert the codeword CW transferred from the I/O gating circuit 370 or the main data MD transferred from the ECC engine 375 to the serial data to output the converted serial data as the data DQ. In some embodiments, when the read operation is performed, the memory device 30 may convert the main data MD provided from the ECC engine 375 to the serial data through the serializer 381 to provide the converted serial data to the memory controller 100 of FIG. 1.

The deserializer 383 may convert serial data to parallel data. For example, the deserializer 383 may be a p:q deserializer that converts p-bit serial data to q-bit parallel data. Here, p and q may be positive numbers, and q may be greater than p. The data DQ may be the serial data. For example, the deserializer 383 may convert the data DQ received from the outside to the parallel data to output the converted parallel data to the ECC engine 375 as the main data MD. In some embodiments, when the write operation is performed, the memory device 30 may convert the data DQ provided from the outside to the parallel data through the deserializer 383 to provide the converted parallel data to the ECC engine 375.

On the other hand, the data I/O buffer 380 may determine whether the data I/O buffer 380 performs an operation converting the data DQ received from the outside to the parallel data based on an input/output control signal CTRL_IO. Specifically, when the data I/O buffer 380 receives the input/output control signal CTRL_IO having an enable level, the data I/O buffer 380 may output the data DQ to the deserializer 397 as a register main data RG_MD without performing the operation converting the data DQ to the parallel data.

Additionally, the data I/O buffer 380 may determine whether the data I/O buffer 380 performs an operation converting register read data RDD received from the register 395 to serial data based on the input/output control signal CTRL_IO. Specifically, when the data I/O buffer 380 receives the input/output control signal CTRL_IO having an enable level, the data I/O buffer 380 may output the register read data RDD to the outside as the data DQ without performing the operation converting the register read data RDD to the serial data.

The register control logic 390 may control overall operations of the register row decoder 391, the register 395, the deserializer 397, and the data I/O buffer 380. As described above, the register control logic 390 may be activated when the low latency bit LLB having an enable level is received. For example, the register control logic 390 may generate a control signal so that the register row decoder 391 and the deserializer 397 perform a read operation or a write operation on the register 395. The control signal may include the input/output control signal CTRL_IO, a deserializer control signal CTRL_P, and the like.

In some embodiments, the register control logic 390 may receive the low latency bit LLB and the address ADDR from the memory controller 100 of FIG. 1. Although FIG. 3 shows that the register control logic 390 receives the low latency bit LLB and the address ADDR from the outside, the present disclosure is not limited thereto, and the register control logic 390 may receive the low latency bit LLB and the address ADDR from the address register 330.

The register control logic 390 may perform the register write operation based on the register control signal CTRL_RG, the low latency bit LLB, and the address ADDR. In some embodiments, the register control logic 390 may generate the input/output control signal CTRL_IO, the deserializer control signal CTRL_P, and a register address RG_ADDR.

In some embodiments, the register control logic 390 may include the mapping table. Specifically, the register control logic 390 may determine the register address RG_ADDR corresponding to the received address ADDR, and may generate the mapping table including information on the address ADDR and the register address RG_ADDR corresponding to the address ADDR. For example, the register control logic 390 may generate the mapping table while performing the register write operation.

The register control logic 390 may perform the register read operation based on the register control signal CTRL_RG, the low latency bit LLB, and the address ADDR. The register control logic 390 may read data stored in the register corresponding to the register address RG_ADDR corresponding to the received address ADDR based on the mapping table.

The register control logic 390 may control the control logic 320 through a control signal CTRL_CL. For example, the control signal CTRL_CL may be a signal indicating that the register address corresponding to the received address does not exist within the mapping table. In some embodiments, the control signal CTRL_CL may be a signal indicating that the low latency bit LLB is not enabled. The control logic 320 that receives the control signal CTRL_CL may write the data DQ in the memory cell corresponding to the received address ADDR, or may read the data DQ from the memory cell corresponding to the received address ADDR.

Although FIG. 3 shows that the register control logic 390 is a separate configuration from the control logic 320, the present disclosure is not limited thereto, and the register control logic 390 may be included within the control logic 320.

The register row decoder 391 may select a register to be activated among the plurality of registers based on the register address RG_ADDR.

In some embodiments, the register row decoder 391 may transmit a register enable signal to the register corresponding to the register to be activated. The register enable signal may be a signal that selects the register to be activated among the plurality of registers. In some embodiments, a plurality of register row decoders 391 corresponding to each of a plurality of registers 395 may be provided.

In some embodiments, the register row decoder 391 may generate a plurality of internal clock signals based on a clock received from a clock generator. In this case, each of the plurality of registers may operate based on a separate internal clock signal. The register row decoder 391 may select the register to be activated among the plurality of registers by applying a clock signal having an enable level to the register to be activated.

The register row decoder 391 may store data in the register 395 corresponding to the register address RG_ADDR through the register write operation. When the register row decoder 391 performs the register write operation, the register 395 may receive data to be stored from the deserializer 397.

The register row decoder 391 may read data from the register 395 using the register read operation. When the register row decoder 391 performs the register read operation, the data read from the register 395 may be transferred to the data I/O buffer 380.

The register 395 may store the data DQ received from the memory controller 100 of FIG. 1.

The register 395 may include a plurality of flip-flops. In this case, one flip-flop may store 1 bit of data. For example, the register 395 may be a serial-input serial-output register that may store and output one bit per clock, a serial-input parallel-output register that may store one bit per clock and may output data in parallel per clock, a parallel-input serial-output register that may store a plurality of bits per clock and may output one bit per clock, or a parallel-input parallel-output register that may store a plurality of bits per clock and may output data in parallel per clock. Hereinafter, the register is described assuming that it is the serial-input serial-output register, but the register 395 may have any appropriate structure.

The deserializer 397 may be connected to the register 395, and may parallelize the register main data RG_MD received from the data I/O buffer 380 based on the deserializer control signal CTRL_P. The deserializer 397 may generate parallel write data WRD by parallelizing the received register main data RG_MD using an internal clock signal and a counter value signal. The deserializer 397 may parallelize data according to a size of the register 395 using a counter.

Although not shown in FIG. 3, the deserializer 397 may further include a write driver circuit for storing the register main data RG_MD in the register 395. In this case, the write driver circuit may receive the parallel write data WRD from the deserializer 397 to transfer the received parallel write data WRD to the register corresponding to the received parallel write data WRD.

On the other hand, FIG. 3 shows that the deserializer 397 receives the register main data RG_MD from the data I/O buffer 380, but the present disclosure is not limited thereto. In some embodiments, the deserializer 397 may receive the data DQ received from the outside, may parallelize the data DQ to generate the write data WRD, and may write the generated write data WRD in the register 395. In some embodiments, the register 395 may receive the data DQ received from the outside, and the data DQ in the form of serial data may be immediately written in the register 395.

Additionally, although FIG. 3 shows that the parallel write data WRD is written in the register 395 through the deserializer 397, but the present disclosure is not limited thereto. In some embodiments, the register 395 may receive the codeword CW from the I/O gating circuit 370 or may directly receive data before being written in the memory cell array 310 from the I/O gating circuit 370. In this case, the write data WRD parallelized through the deserializer 397 may not be written in the register 395, and the codeword CW stored in the I/O gating circuit 370 may be written in the register 395.

When the data DQ is written in the memory cell array 310, it takes time for the ECC engine 375 to perform an ECC operation, and it takes time for the I/O gating circuit 370 to store data for a predetermined time. Because only parallelization is performed on the serial data except for unnecessary operations such as the ECC operation and the storage operation so that the parallel data is written in the register 395, a time required for the writing may be reduced.

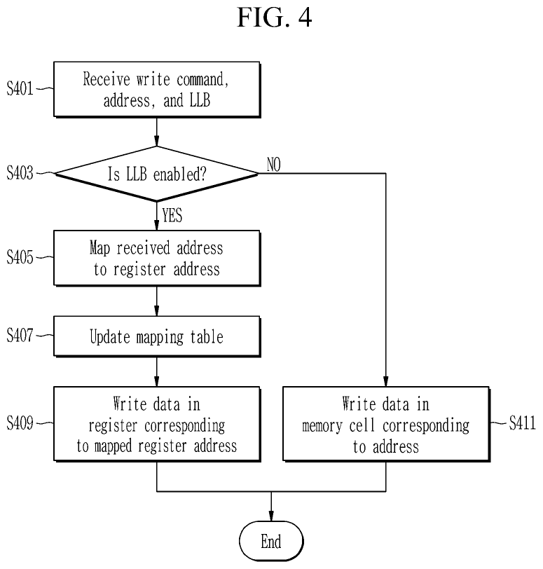

FIG. 4 is a flowchart showing the register write operation according to some embodiments.

First, the register control logic 390 receives the write command, the address, and the LLB (S401).

The register control logic 390 may receive the write command from the control logic 320 through the register control signal CTRL_RG. The register control logic 390 may receive the address ADDR and the low latency bit LLB from the outside.

The register control logic 390 determines whether the low latency bit LLB is enabled (S403).

If the low latency bit LLB is not enabled, the data is written in the memory cell corresponding to the address (S411).

If the low latency bit LLB is not enabled, the register control logic 390 may not be activated. Accordingly, the control logic 320 may write the data DQ in the memory cell corresponding to the address ADDR.

If the low latency bit LLB is enabled, the received address is mapped to the register address (S405).

If the low latency bit LLB is enabled, the register control logic 390 may be activated. The register control logic 390 may map the received address ADDR to the register address RG_ADDR.

Thereafter, the register control logic 390 updates the mapping table (S407).

The register control logic 390 writes the data in the register corresponding to the mapped register address (S409).

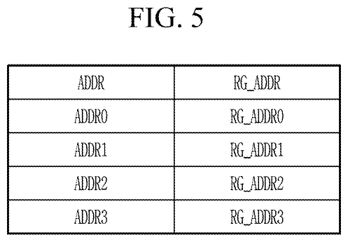

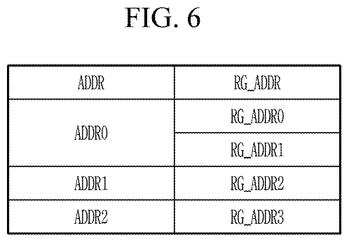

The operations S405 and S407 in which the register control logic 390 generates the mapping table will be described with reference to FIGS. 5 and 6.

FIG. 5 is a view showing the mapping table according to some embodiments. Specifically, FIG. 5 is a view showing the mapping table when a size of the register within the memory device 30 is larger than a size of the received data DQ.

It is assumed that the memory device 30 includes a plurality of registers. Each register may include a separate register address RG_ADDR. In this case, it is assumed that a first register address RG_ADDR0 is already mapped to a first address ADDR0 within the mapping table.

For example, the register control logic 390 may receive a second address (ADDR1) from the outside.

In some embodiments, the register control logic 390 may map the address ADDR received from the control logic 320 to an arbitrary register address when it receives the write command.

The register control logic 390 may map the second address (ADDR1) to one of a second register address RG_ADDR1, a third register address RG_ADDR2, and a fourth register address RG_ADDR3. The register control logic 390 may determine that the second address (ADDR1) is mapped to the third register address RG_ADDR2. Thereafter, the register control logic 390 may update the mapping table.

In some embodiments, the register control logic 390 may map the received address ADDR to the register address according to a predetermined order. For example, the register control logic 390 may sequentially map the received address ADDR to the register address RG_ADDR. In this case, because the first address ADDR0 is mapped to the first register address RG_ADDR0, the register control logic 390 may map the second address (ADDR1) received for the second time to the second register address RG_ADDR1.

FIG. 6 is a view showing the mapping table according to some embodiments.

Specifically, FIG. 6 is a view showing the mapping table when a size of the register within the memory device 30 is smaller than a size of the received data DQ.

It is assumed that the memory device 30 includes a plurality of registers. Each register may include a separate register address RG_ADDR. In this case, it is assumed that a first register address RG_ADDR0 and a second register address RG_ADDR1 are already mapped to a first address ADDR0 within the mapping table.

For example, the register control logic 390 may receive a second address (ADDR1) from the outside.

In some embodiments, the register control logic 390 may map the address ADDR received from the control logic 320 to an arbitrary register address when it receives the write command. On the other hand, as described above, a type of a signal that may be exchanged between the memory device 30 and the memory controller 100 of FIG. 1 may be preset. Based on the preset signal type and the size of the register, the register control logic 390 may determine that the data DQ to be written in the memory cell may not be stored in one register. Accordingly, the register control logic 390 may divide and store one data DQ in the plurality of registers, and may map a plurality of register addresses RG_ADDR to one address ADDR. Here, a size obtained by summing sizes of the plurality of registers may be greater than or equal to a size of the data DQ.

As shown in FIG. 6, the register control logic 390 may determine that the second address (ADDR1) is mapped to a third register address RG_ADDR2 and a fourth register address RG_ADDR3. Thereafter, the register control logic 390 may update the mapping table.

Thereafter, the register control logic 390 may control the register row decoder 391 to perform the write operation for the received data DQ in the register corresponding to the mapped plurality of register addresses RG_ADDR. For example, if the register control logic 390 completes the write operation for a part of the data DQ in a first register among the plurality of registers, it performs the write operation for the remaining part of the data DQ in a second register among the plurality of registers.

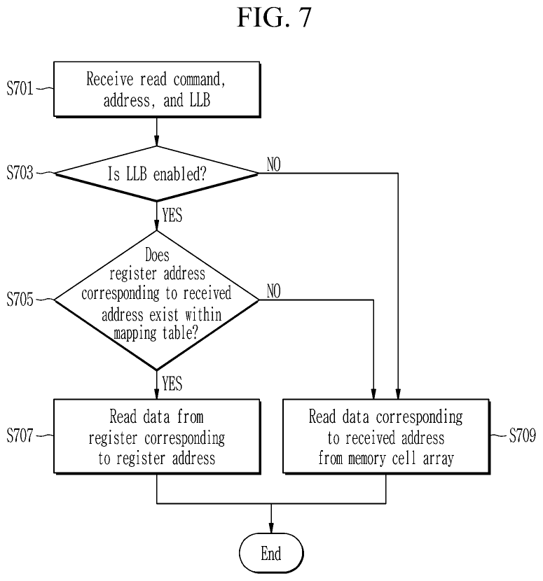

FIG. 7 is a flowchart showing the register read operation according to some embodiments.

First, the register control logic 390 receives the read command and the address (S701).

The register control logic 390 may receive the read command from the control logic 320 through the register control signal CTRL_RG. The register control logic 390 may receive the address ADDR and the low latency bit LLB from the outside (i.e., external to the memory device 30).

The register control logic 390 determines whether the low latency bit LLB is enabled (S703).

If the low latency bit LLB is not enabled, the data corresponding to the received address is read from the memory cell array (S709).

If the low latency bit LLB is not enabled, the register control logic 390 may not be activated. Accordingly, the register control logic 390 may allow the control logic 320 to read the data DQ from the memory cell corresponding to the address ADDR through the control signal CTRL_CL.

If the low latency bit LLB is enabled, the register control logic 390 determines whether the register address corresponding to the received address exists within the mapping table (S705).

If the low latency bit LLB is enabled, the register control logic 390 may be activated. The register control logic 390 may determine the register address RG_ADDR corresponding to the received address ADDR based on the mapping table including information on the mapping relationship between the address ADDR and the register address RG_ADDR.

If there is no register address corresponding to the address, the register control logic 390 performs the step S709.

In some embodiments, the register control logic 390 may allow the control logic 320 to read the data DQ from the memory cell corresponding to the address ADDR through the control signal CTRL_CL.

If the register address corresponding to the address exists, the register control logic 390 reads data from the register corresponding to the register address (S707).

For example, referring to FIG. 5 together with FIG. 7, when the register control logic 390 receives the first address ADDR0, the register control logic 390 may determine that the first register address RG_ADDR0 is mapped to the first address ADDR0. Accordingly, the register control logic 390 may read data from the register corresponding to the first register address RG_ADDR0.

For example, referring to FIG. 6 together with FIG. 7, when the register control logic 390 receives the first address ADDR0, the register control logic 390 may determine that the first register address RG_ADDR0 and the second register address RG_ADDR1 are mapped to the first address ADDR0. Accordingly, the register control logic 390 may read data from the registers corresponding to the first register address RG_ADDR0 and the second register address RG_ADDR1. In some embodiments, the register control logic 390 may read data from the register corresponding to the first register address RG_ADDR0, and then may read data from the register corresponding to the second register address RG_ADDR1. In some embodiments, the register control logic 390 may read data from the register corresponding to the second register address RG_ADDR1, and then may read data from the register corresponding to the first register address RG_ADDR0. However, the present disclosure is not limited thereto, and when a plurality of register addresses RG_ADDR are mapped to one address ADDR, an order in which the register control logic 390 reads data may be preset. A method by which the register control logic 390 reads the data may be appropriately selected according to a method of writing data. For example, when the parallel write data WRD or the codeword CW that is the parallel data is written in the register 395 through the deserializer 397, the memory device 30 may serialize the data read from the register 395 to output the serialized data. In this case, the register control logic 390 may control the serializer 381 within the data I/O buffer 380 to convert the read data RDD read from the register to the serial data through the input/output control signal CTRL_IO. The converted data may be read to the outside.

In some embodiments, if the data DQ is written in the register 395 without converting the data DQ to parallel data, the register control logic 390 may immediately read the read data RDD read from the register 395 without converting the read data RDD to serial data.

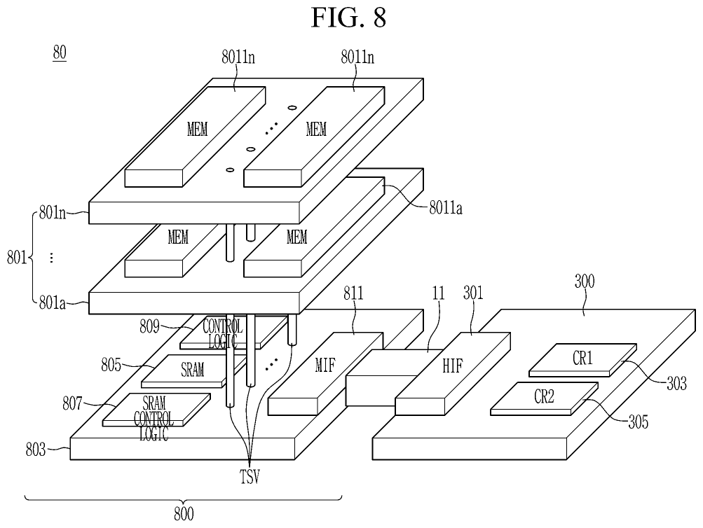

FIG. 8 is a perspective view showing a memory system according to some embodiments.

Referring to FIG. 8, the memory system 80 may include the host device 300 and a memory device 800. The memory device 800 may include a plurality of memory dies 801 and a buffer die 803, and the memory die 801 may include memory dies 801a, . . . , 801n sequentially stacked.

In some embodiments, the host device 300 may include the memory controller 100 of FIG. 1, and the memory controller 100 and the memory device 800 may constitute or be included in the memory system. However, the present disclosure is not limited thereto, and the memory controller 100 of FIG. 1 may be included in the memory device 800, and a memory interface 811 may include the memory controller. In this case, the memory interface 811 may include receivers, line drivers, memory request buffers, a scheduling logic, a row/column decode logic, a refresh logic, data-input and data-output buffers, a clock generator, or the like.

The memory device 800 may include at least one buffer die 803 and the plurality of memory dies 801 vertically stacked. FIG. 8 shows one buffer die and two memory dies, but the present disclosure is not limited thereto, and the memory device 800 may include any number of memory dies. Additionally, although FIG. 8 shows that the buffer die 803 is vertically stacked at an upper portion of the memory die 801, the present disclosure is not limited thereto, and may have various shapes. For example, the memory dies 801 other than the buffer die 803 in the memory device 800 may be vertically stacked, and the buffer die 803 may be electrically connected to the stacked memory dies 801 through an interposer or a base substrate.

The buffer die 803 may include the memory interface (MIF) 811 and a logic for enabling access to memory integrated circuits (MEM) 8011a, . . . , 8011n formed at the memory die 801. For example, the buffer die 803 may include a control logic 809, an SRAM 805, and an SRAM control logic 807.

The SRAM 805 may store data received from the SRAM control logic 807. Here, the data may be data received from the host device 300. For example, the SRAM 805 may include a plurality of transistors and a plurality of inverters. An SRAM address may be assigned to each of the plurality of SRAMs 805.

The memory device 800 may include the SRAM 805 having an appropriate size depending on a type of the memory system 80. The size of the SRAM 805 may be preset based on the number of DQ pins and a burst length BL of the memory. For example, the SRAM 805 may have a size corresponding to one page of the memory die 801.

The SRAM control logic 807 may be activated when the low latency bit LLB is in an enabled state.

In some embodiments, the SRAM control logic 807 may include a mapping table that maps the address ADDR to the SRAM address. Additionally, the mapping table may store information on whether the data DATA is written in the SRAM address. The SRAM control logic 807 may convert the received address ADDR to the SRAM address based on the mapping table.

If the control logic 809 receives the write command and the SRAM control logic 807 is activated, the SRAM control logic 807 may write the received data DATA in the SRAM 805. If the control logic 809 receives the read command and the SRAM control logic 807 is activated, the SRAM control logic 807 may read data from the SRAM 805.

The memory interface circuit 811 may be electrically and/or logically connected to a through silicon via TSV. The control logic 809 may transfer data provided from at least one of the memory dies 801 through the through silicon via to the host device 300 through the memory interface circuit 811. The control logic 809 may transfer data received from the host device 300 through the memory interface circuit 811 to at least one of the memory dies 801 through the through silicon via.

The plurality of memory dies 801 may be connected to the buffer die 803 through the through silicon via TSV.

Each of the plurality of memory dies 801 may include the plurality of memory integrated circuits (MEM) 8011a, . . . , 8011n. Each of the plurality of memory integrated circuits 8011a, . . . , 8011n may include a plurality of memory banks that store data.

Descriptions of the host device 300 and the interconnect device 11 of FIG. 8 may be the same as or similar to the descriptions of the host device 300 and the interconnect device 11 described with reference to FIG. 2.

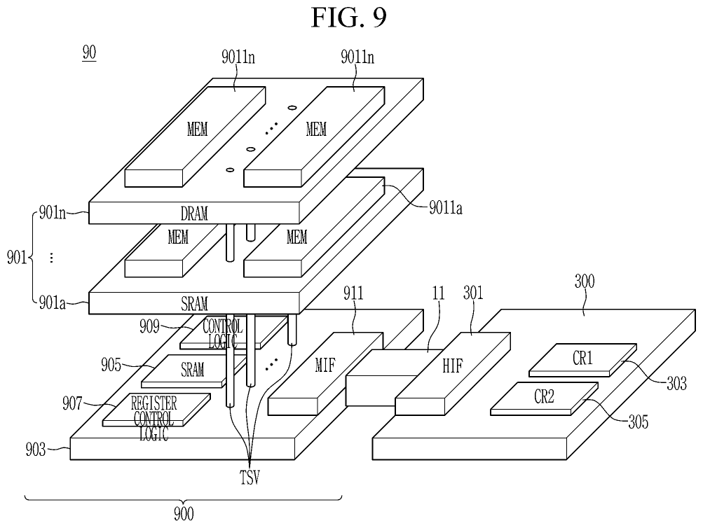

FIG. 9 is a perspective view showing a memory system according to some embodiments.

Referring to FIG. 9, the memory system 90 may include the host device 300 and a memory device 900. The memory device 900 may include a plurality of memory dies 901 and a buffer die 903, and the memory dies 901 may include memory dies sequentially stacked.

In some embodiments, the host device 300 may include the memory controller 100 of FIG. 1, and the memory controller 100 and the memory device 900 may constitute or be included in the memory system. However, the present disclosure is not limited thereto, and the memory controller 100 of FIG. 1 may be included in the memory device 900, and a memory interface circuit 911 may include the memory controller. In this case, the memory interface circuit 911 may include receivers, line drivers, memory request buffers, a scheduling logic, a row/column decode logic, a refresh logic, data-input and data-output buffers, a clock generator, and/or the like.

The memory system 90 may include various computer systems including a notebook computer, a tablet computer, a desktop computer, a server, a network router, a switch, a hub, a computing mobile phone, a personal portable information terminal, and/or the like. On the other hand, an example in which the memory system 90 includes the host device 300 connected to the stacked memory device 900 through the interconnect device 11 is shown in the drawings, but the memory system 90 may include various configurations such as a display device, a storage device, an input device (e.g., a mouse or a keyboard), and the like that are not shown in the drawings.

The memory device 900 may include at least one buffer die 903 and the plurality of memory dies 901 vertically stacked. FIG. 9 shows one buffer die and two memory dies, but the present disclosure is not limited thereto, and the memory device 900 may include any number of memory dies. Additionally, although FIG. 9 shows that the buffer die 903 is vertically stacked at an upper portion of the memory dies 901, but the present disclosure is not limited thereto, and may have various shapes. For example, the memory dies 901 other than the buffer die 903 in the memory device 900 may be vertically stacked, and the buffer die 903 may be electrically connected to the stacked memory dies 901 through an interposer or a base substrate.

The buffer die 903 may include the memory interface 911 and a logic for enabling access to memory integrated circuits (MEM) 9011a, . . . , 9011n formed at the memory dies 901. For example, the buffer die 903 may include a control logic 909, a register control logic 907, and a register 905 (such as an SRAM).

The memory interface circuit 911 may be electrically and/or logically connected to a through silicon via TSV. The control logic 909 may transfer data provided from at least one of the memory dies 901 through the through silicon via to the host device 300 through the memory interface circuit 911. The control logic 909 may transfer data received from the host device 300 through the memory interface circuit 911 to at least one of the memory dies 901 through the through silicon via.

The plurality of memory dies 901 may be connected to the buffer die 903 through the through silicon via TSV.

Each of the plurality of memory dies 901 may include the plurality of memory integrated circuits 9011a, . . . , 9011n. Each of the plurality of memory integrated circuits 9011a, . . . , 9011n may include a plurality of memory banks that store data.

Each of the plurality of memory dies 901 may be a dynamic random access memory (DRAM) including a plurality of volatile memory cells such as a thyristor random access memory (TRAM), a static random access memory (SRAM), a double data rate synchronous dynamic random access memory (DDR SDRAM), and/or the like. In some embodiments, each of the plurality of memory dies 901 may be a phase change random access memory (PRAM) including resistive memory cells, a resistive random access memory (RRAM), a magnetic random access memory (MRAM), and/or a ferroelectric random access memory (FRAM).

As shown in FIG. 9, a first memory die 901a may include an SRAM, and the remaining memory die 901n may include a DRAM. In this case, a separate address may be assigned to each memory die.

First, the memory controller 100 of FIG. 1 may determine the address ADDR where the data is stored and/or the low latency bit LLB based on a type of data to be transmitted. For example, in a case in which the data is frequently used and in a case in which the data requires a fast processing speed, the memory controller 100 may set the data to be stored in the register or SRAM 905 on the buffer die 903. Additionally, in a case in which the data is not frequently used and requires a fast processing speed, the memory controller 100 may set the address ADDR so that the data is stored in the first memory die 901a including the SRAM. Additionally, in a case in which the data is not frequently used and does not require a fast processing speed, the memory controller 100 may set the address ADDR so that the data is stored in the second memory die 901n including the DRAM.

Descriptions of the host device 300 and the interconnect device 11 of FIG. 9 may be the same as or similar to the descriptions of the host device 300 and the interconnect device 11 described with reference to FIG. 2.

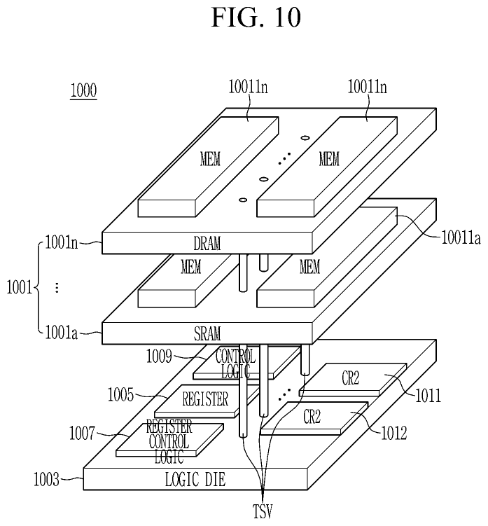

FIG. 10 is a perspective view showing a memory device according to some embodiments.

Referring to FIG. 10, the memory device 1000 may include a plurality of memory dies 1001 and a logic die 1003, and the memory dies 1001 may include memory dies sequentially stacked.

The memory device 1000 may include at least one logic die 1003 and the plurality of memory dies 1001 vertically stacked. FIG. 10 shows one logic die and two memory dies, but the present disclosure is not limited thereto, and the memory device 1000 may include any number of memory dies 1001. Additionally, although FIG. 10 shows that the logic die 1003 is vertically stacked at an upper portion of the memory dies 1001, but the present disclosure is not limited thereto, and may have various shapes. For example, the memory dies 1001 other than the logic die 1003 in the memory device 1000 may be vertically stacked, and the logic die 1003 may be electrically connected to the stacked memory dies 1001 through an interposer or a base substrate.

The logic die 1003 may include a logic for enabling access to memory integrated circuits (MEM) 10011a, . . . , 10011n formed at the memory dies 1001. For example, the logic die 1003 may include a control logic 1009, a register control logic 1007, a register 1005, and processor cores (CR1 and CR2) 1011 and 1012.

The process cores 1011 and 1012 may generate commands for controlling an overall operation of the memory device 1000. For example, the processor cores 1011 and 1012 may include various types of process cores such as a central processing unit (CPU) core, a graphic processing unit (GPU), a digital signal processor (DSP), and the like, and a combination thereof.

The plurality of memory dies 1001 may be electrically and/or logically connected to the logic die 1003 through a through silicon via TSV.

Each of the plurality of memory dies 1001 may include the plurality of memory integrated circuits 10011a, . . . , 10011n. Each of the plurality of memory integrated circuits 10011a, . . . , 10011n may include a plurality of memory banks that store data.

The memory device 1000 of FIG. 10 may be implemented in a vertically stacked arrangement so that electric power and a signal are transferred between the logic die 1003 and the memory dies 1001 using dense through silicon vias (TSVs) or other vertical interconnects. Although FIG. 10 shows the TSVs as a set of centrally concentrated rows, the present disclosure is not limited thereto, and the TSVs may be distributed across planes of the semiconductor dies.

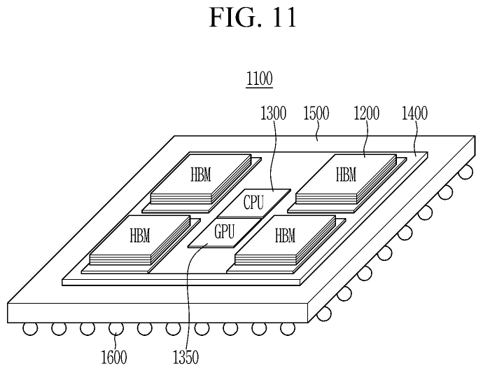

FIG. 11 is a perspective view showing an example of a semiconductor package including the stacked memory device according to some embodiments.

Referring to FIG. 11, the semiconductor package 1100 may include one or more stacked memory devices 1200, a central processing unit 1300, and a graphics processor 1350. The stacked memory device 1200, the central processing unit 1300, and the graphics processor 1350 may be installed on an interposer 1400, and the interposer 1400 may be installed on a package substrate 1500. The central processing unit 1300 and the graphics processor 1350 may be implemented to perform a function of the host device described above.

The stacked memory device 1200 may be implemented in various forms, and in some embodiments, the stacked memory device 1200 may be a stacked memory device having a form of a high bandwidth memory (HBM) in which a plurality of layers are stacked as described above. The stacked memory device 1200 may include the buffer die or the logic die described with reference to FIGS. 1 to 10.

In some embodiments, each of the stacked memory devices 1200, the central processing unit 1300, and the graphics processor 1350 (i.e., GPU) may include a physical layer (PHY), and communication may be performed between a memory controller included in each of the stacked memory devices 1200 and a memory controller included in the central processing unit 1300 through the physical layer (PHY). On the other hand, when the stacked memory device 1200 includes a direct access region, a test signal may be provided inside the stacked memory device 1200 through a conductive means (e.g., a solder ball 1600) installed at a lower portion of the package substrate 1500 and the direct access region.

As described above, the memory device and the operating method of the memory device according to the embodiments of the present disclosure may store data requiring a fast input/output speed in the register or the storage device on the buffer die within the memory device so that a time required for data input/output and power consumption are reduced. Accordingly, the memory device and the operating method of the memory device may shorten a data processing time, and because the memory device includes a separate data storage device in an empty space on the buffer die, the memory device and the operating method of the memory device may not affect a size of the memory device, and may improve performance of the memory system.

While this disclosure has been described in connection with what is presently considered to be practical embodiments, it is to be understood that the disclosure is not limited to the disclosed embodiments, but, on the contrary, is intended to cover various modifications and equivalent arrangements included within the scope of the appended claims.

What is claimed is:

1. A memory device comprising:
a plurality of memory banks;
a plurality of registers;
a data I/O buffer configured to transmit and receive data; and
a control logic configured to receive a low latency bit and an address that is preset according to a type of the data,
wherein the control logic is configured to determine a logic level of the low latency bit, and
wherein, based on the low latency bit, the memory device is configured to store the data in a memory bank corresponding to the address among the plurality of memory banks or a register corresponding to the address among the plurality of registers, or configured to read the data from the memory bank corresponding to the address or the register corresponding to the address.

2. The memory device of claim 1, further comprising:
a register control logic that is configured to be activated when the low latency bit is at a first level and is configured to perform a register write operation to store the data in the plurality of registers and is configured to perform a register read operation to read the data from the plurality of registers,
wherein, when the low latency bit is at a second level that is different from the first level, the control logic is configured to store the data in the memory bank corresponding to the address or configured to read the data from the memory bank corresponding to the address.

3. The memory device of claim 2, wherein when the register write operation is performed, the register control logic is configured to map the address to at least one register address among a plurality of register addresses and is configured to generate a mapping table including a mapping relationship between the address and the register address.

4. The memory device of claim 3, wherein when the register write operation is performed, and when the data has a first size and the register corresponding to the address has a second size greater than the first size, the register control logic is configured to map the address to one of the plurality of register addresses.

5. The memory device of claim 3, wherein when the register write operation is performed, and when the data has a first size and the register corresponding to the address has a second size greater than the first size, the register control logic is configured to map the address to register addresses among the plurality of register addresses.

6. The memory device of claim 3, further comprising:
a deserializer that is electrically or logically connected to the plurality of registers and is configured to generate parallel data by parallelizing input data,
wherein the data I/O buffer is configured to transfer external data to the deserializer based on an input/output control signal, and
wherein the parallel data is stored in the plurality of registers.

7. The memory device of claim 3, wherein when the register read operation is performed, the register control logic is configured to transmit a control signal that indicates to the control logic to read the data from the memory bank corresponding to the address when the register address corresponding to the address does not exist in the mapping table.

8. The memory device of claim 3, wherein when the register read operation is performed, the register control logic is configured to read the data from at least one register corresponding to the at least one register address that is mapped to the address based on the mapping table.

9. The memory device of claim 1, further comprising:
a plurality of memory dies; and
a buffer die,
wherein the plurality of memory dies comprises at least one memory bank among the plurality of memory banks,
wherein the buffer die comprises the plurality of registers and the control logic, and
wherein the plurality of memory dies are stacked on the buffer die and are interconnected to one another by a plurality of through silicon vias.

10. A memory device comprising:
a buffer die configured to transmit and receive data to and from a host device, wherein the buffer die includes a plurality of registers;
a plurality of memory dies that are stacked on the buffer die, wherein the plurality of memory dies include a plurality of memory banks; and
a plurality of through silicon vias that electrically connect the buffer die to respective ones of the plurality of memory dies,
wherein the buffer die further comprises a control logic configured to receive a low latency bit and an address that is preset according to a type of the data,
wherein the control logic is configured to determine a logic level of the low latency bit, and
wherein, based on the low latency bit, the memory device is configured to store the data in a memory bank corresponding to the address among the plurality of memory banks or store the data in a register corresponding to the address among the plurality of registers, or read the data from the memory bank corresponding to the address or the register corresponding to the address.

11. The memory device of claim 10, wherein the buffer die further comprises a plurality of static random access memories (SRAMs) configured to store the data.

12. The memory device of claim 10, wherein each of the plurality of memory dies includes at least one of a dynamic random access memory (DRAM), a thyristor random access memory (TRAM), a static random access memory (SRAM), or a double data rate synchronous dynamic random access memory (DDR SDRAM).

13. The memory device of claim 10, wherein the buffer die further includes a register control logic that is configured to be activated when the low latency bit is at a first level and is configured to perform a register write operation to store the data in the plurality of registers and is configured to perform a register read operation to read the data from the plurality of registers, and
wherein, when the low latency bit is at a second level that is different from the first level, the control logic is configured to store the data in the memory bank corresponding to the address or configured to read the data from the memory bank corresponding to the address.

14. The memory device of claim 13, wherein when the register write operation is performed, the register control logic is configured to map the address to at least one register address among a plurality of register addresses based on a size of the data and a size of each of the plurality of registers, and is configured to generate a mapping table including a mapping relationship between the address and the register address.

15. The memory device of claim 14, wherein when the register read operation is performed, the register control logic is configured to read the data from at least one register corresponding to the at least one register address mapped to the address based on the mapping table.

16. An operating method of a memory device, comprising:
receiving, by a memory device that comprises a buffer die including a plurality of registers and at least one memory die stacked on the buffer die and including a plurality of memory banks, data, a low latency bit that is preset according to a type of the data, a command, and an address from a host device; and
determining a logic level of the low latency bit,
wherein when the command is a write command, the operating method of the memory device comprises:
mapping the address to at least one register address among a plurality of register addresses when the logic level of the low latency bit is at a first level;
generating a mapping table including a mapping relationship between the address and the register address; and
storing the data in a register corresponding to the mapped register address.

17. The operating method of claim 16, wherein when the command is the write command and the logic level of the low latency bit is at a second level that is different from the first level, the operating method of the memory device further comprises storing the data in a memory bank corresponding to the address among the plurality of memory banks.

18. The operating method of claim 16, wherein the mapping of the address comprises mapping the address to at least one register address among the plurality of register addresses based on a size of the data and respective sizes of each of the plurality of registers.

19. The operating method of claim 16, wherein when the command is a read command, the operating method of the memory device further comprises:
determining whether a register address mapped to the address exists within a mapping table when the logic level of the low latency bit is at a first level; and
reading the data from a register corresponding to the register address when the mapped register address exists.

20. The operating method of claim 19, wherein when the mapped register address does not exist, the operating method of the memory device further comprises:
reading the data from a memory bank corresponding to the address among the plurality of memory banks.
